(19) United States
(12) Patent Application Publication
(10) Pub. No.: US 2005/0066881 A1
(43) Pub. Date: Mar. 31, 2005

(54) Continuous production method for crystalline silicon and production apparatus for the same

(75) Inventors: Katsumi Nakagawa, Kanagawa (JP); Shunichi Ishihara, Kyoto (JP); Hiroshi Sato, Shiga (JP); Shoji Nishida, Kanagawa (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/938,509

(22) Filed: Sep. 13, 2004

(30) Foreign Application Priority Data
Sep. 25, 2003 (JP) 2003-333091

(51) Int. Cl. C30B 15/00; C30B 21/06; C30B 27/02; C30B 28/10; C30B 30/04

(52) U.S. Cl. 117/18; 117/208; 117/214

(57) ABSTRACT

Provided is a continuous production method for crystalline silicon, including: retaining melted silicon in a crucible; solidifying a portion close to a surface of raw material silicon by providing a negative temperature gradient upward from the crucible; holding the solidified crystalline silicon by a pulling means; and pulling the solidified crystalline silicon at a predetermined rate, while shaping a sectional shape of the solidified crystalline silicon by bringing the solidified crystalline silicon in contact with an opened heater when the solidified crystalline silicon passes through an opening portion of the opened heater having an opening of a predetermined shape and maintained at a temperature higher than a melting point of the raw material silicon. The method allows continuous production of a crystalline silicon ingot having uniform crystallinity or impurity concentration and high quality at low cost even when low purity raw material silicon such as metallurgical grade silicon is used.

### BACKGROUND OF THE INVENTION

1. Field of the Invention

The present invention relates to a continuous production method for polycrystalline silicon having satisfactory crystallinity and a production apparatus suitable for carrying out the method.

2. Related Background Art

Polycrystalline silicon is used in various applications. Polycrystalline silicon used as a primary material for semiconductor single crystal silicon may have an indefinite shape. Polycrystalline silicon used as a working member of a substrate for a polycrystalline silicon solar cell, a sputtering target, an electrode for plasma etching, or the like may be obtained by: forming an ingot having a predetermined shape such as a rectangular parallelepiped and a cylinder; and machining the ingot into a final product. Solar cell substrates are tightly arranged to form a module, and each thereof preferably has a shape of a square or a rectangle for preventing reduction in substantial efficiency of a module caused by dead spaces between the substrates, for example. An ingot of polycrystalline silicon may be formed using a crucible having an inner shape of a rectangular parallelepiped, and sliced. Thus, a substrate having a desired shape can be processed more easily with a smaller waste of a raw material compared to a single crystal substrate, which basically must be sliced from a cylindrical ingot. Further, polycrystalline silicon growth may be carried out at high speed using a large crucible, which provides higher productivity compared to that of single crystal silicon growth requiring precise control for maintaining a diameter of an ingot to a predetermined value. Thus, a ratio of polycrystalline silicon solar cells with respect to total production of solar cells has gradually increased recently.

Crystal grains of semiconductor polycrystals such as silicon, that is, of polycrystalline silicon are desirably grown large uniformly for excellent electrical properties. The crystal grains grown large uniformly are excellent for machining as well besides electrical properties. From this perspective, a particularly preferable production method for polycrystalline silicon is a unidirectional solidification method. The unidirectional solidification method is widely used in metal ingot production or the like, and various improvements have been made. Japanese Patent Application Laid-Open No. H11-011924 discloses an example of the unidirectional solidification method used for silicon.

FIG. 3 shows a basic structure of a polycrystalline silicon growth apparatus employing the unidirectional solidification method. Silicon is retained in a quartz glass crucible 300. The retained silicon is heated by heaters 301 and 302 for melting the whole once. Then a negative temperature gradient is formed downward, and upward growth of polycrystalline silicon 303 gradually begins from a base. A region of melted silicon 305 decreases gradually, and the whole finally converts into polycrystals. At the same time, a grain boundary 304 of the polycrystals extends in an almost vertical direction. The heaters 301 and 302 are vertically divided in two for controlling output balance of the two heaters and for providing a predetermined temperature gradient. The crucible may be cooled from the base using a cooling mechanism 306 for the same purpose after silicon is melted.

A unidirectional solidification method has another large advantage. A concentration of impurities in a solid is often lower than a concentration of impurities dissolved in a liquid when a liquid solidifies into a solid. An equilibrium segregation coefficient represents a ratio of the concentrations. An equilibrium segregation coefficient of 1 indicates that concentrations of the impurities in the solid and the liquid are the same, and an equilibrium segregation coefficient of less than 1 indicates a relatively low concentration of impurities in the solid. As impurities in silicon, typical dopant elements such as boron and phosphorus each have a segregation coefficient of 0.8 and 0.35, which is close to 1 and indicates a small segregation effect. On the other hand, heavy metal elements such as iron and nickel each have a segregation coefficient of 8×10⁻⁶ and 3×10⁻⁵, which is extremely small and indicates a large segregation effect (see, Fumio Shimura, “Semiconductor Silicon Crystal Technology”, p. 57, Maruzen Co., Ltd.). Thus, heavy metal impurities gradually accumulates on the melted silicon 305 remained in an upper portion with unidirectional solidification. However, a concentration of heavy metal impurities significantly reduces in solidified polycrystalline silicon except in a vicinity of a surface. Thus, even low purity raw material silicon such as inexpensive unpurified silicon (metallurgical grade silicon) prepared by directly reducing silica stone may be easily and efficiently purified regarding heavy metal impurities.

However, a conventional unidirectional solidification method still had many problems in terms of characteristics and production cost of finished polycrystalline silicon. For example, the method shown in FIG. 3 basically employs a batch process, and thus melting of charged raw material silicon or cooling of solidified polycrystalline silicon to room temperature require longer time than time required for crystal growth itself. Production of large-scale polycrystalline silicon for improved productivity particularly results in longer time required for melting or solidification, and an initial purpose is hardly achieved. A release agent such as expensive silicon nitride powder must be applied to an inner surface of the crucible 300 in advance to prevent clinging of the finished polycrystalline silicon while being taken out of the crucible. Even so, an expensive quartz glass crucible often broke due to thermal stress in cooling of the polycrystalline silicon after solidification.

Crystal uniformity is another problem. That is, in unidirectional solidification, crystal grains are small in a portion close to a crucible base during initial growth and reach a certain size through coalescence of the crystal grains with progress in solidification. Thus, the crystal grains are small in the vicinity of the crucible base. Further, impurities from the crucible may be diffused into the vicinity of the crucible base. When raw material silicon contains metal impurities, the impurities remain in the melted silicon 305 due to a segregation effect with progress in growth. A concentration of the impurities gradually increases, and thus, a concentration of impurities in polycrystalline silicon tends to increase as approaching to the surface. Impurities from an inner wall of the crucible may also diffuse into the crystals. Thus, only a central portion of an ingot may have high quality in the grown polycrystalline silicon. Countermeasures for such problems include: placing a seed crystal plate 307 on a base of the crucible 300 to improve crystallinity in the vicinity of the base and to prevent contamination from the base; and using a high purity product for a release agent applied to the crucible 300 or to an inner wall of the crucible. However, both countermeasures include factors for cost increase.

An electromagnetic casting method is a known production method for polycrystalline silicon with a longer growth time per batch capable of preventing clinging of the polycrystalline silicon and an inner wall of the crucible or of preventing contamination from the inner wall of the crucible. Japanese Patent Application Laid-Open No. H04-342496 illustrates an example of the electromagnetic casting method (FIG. 5). According to the method, melted silicon is held by a magnetic field even without the crucible, and thus, no impurities diffuse from an environment. Further, raw material silicon can be continuously supplied, and thus, growth per batch may be continued for a long time. However, use of low purity raw material silicon in the method gradually increases a concentration of impurities in the melted silicon and further increases a concentration of impurities in a polycrystalline silicon ingot, hindering unlimitedly continuous growth. In this method, high temperature silicon may scatter at once if a magnetic field holding the melted silicon should break due to power failure or the like.

Further, Japanese Patent Application Laid-Open No. H06-345584 describes: supply of a semiconductor material during crystal growth; and provision of an induction coil in a pulling portion. However, the induction coil described herein has a function of melting a semiconductor but is not in contact with an ingot, and thus cannot directly shape a cross section of the ingot.

Further, Japanese Patent Publication (Kokoku) No. H02-036560 describes flow of a melt as a countermeasure for concentrating of impurities.

### SUMMARY OF THE INVENTION

The present invention has been made in view of the above, and an object of the present invention is therefore to provide: a method of continuously producing for a long period of time a crystalline silicon ingot having a predetermined sectional shape such as a square, which is suitably employed as, for example, a substrate for solar cell, by maintaining the ingot in a satisfactory state with uniform crystallinity or impurity concentration; and an apparatus suitable for carrying out the method.

The inventors of the present invention have intensively carried out research and development for attaining the above object, and have found the following optimal continuous production method for crystalline silicon and apparatus for the same.

That is, the present invention provides a continuous production method for crystalline silicon, characterized by including: retaining melted silicon in a crucible; solidifying a portion close to a surface of raw material silicon by providing a negative temperature gradient upward from the crucible; holding the solidified crystalline silicon by a pulling means; and pulling the solidified crystalline silicon at a predetermined rate, while shaping a sectional shape of the solidified crystalline silicon by bringing the solidified crystalline silicon in contact with an opened heater when the solidified crystalline silicon passes through an opening portion of the opened heater having an opening of a predetermined shape and maintained at a temperature higher than a melting point of the raw material silicon.

Further, the present invention provides a continuous production method for crystalline silicon, characterized in that the crystalline silicon pulling means has a seed crystal plate of crystalline silicon fixed at a tip; and the seed crystal plate is brought in contact with a surface of the melted silicon to begin solidification of silicon.

Further, the present invention provides a continuous production method for crystalline silicon, characterized in that the melted silicon is maintained at a predetermined liquid level by supplying the raw material silicon into the crucible during pulling of the crystalline silicon.

Further, the present invention provides a continuous production method for crystalline silicon, characterized in that the melted silicon is maintained at a predetermined liquid level by discharging the melted silicon retained in the crucible to outside of the crucible at a predetermined ratio and supplying the raw material silicon into the crucible during pulling of the crystalline silicon.

Further, the present invention provides a continuous production method for crystalline silicon, characterized in that the raw material silicon supplied is prepared by melting in another crucible in advance.

Further, the present invention provides a continuous production method for crystalline silicon, characterized in that the raw material used is metallurgical grade silicon.

Further, the present invention provides a continuous production method for crystalline silicon characterized in that a predetermined portion in an upper portion of the crystalline silicon is cut off every time the pulled crystalline silicon reaches a predetermined length; and the remaining crystalline silicon is continuously pulled by the pulling means.

Further, the present invention provides a continuous production method for crystalline silicon, characterized in that the crystalline silicon has a sectional shape of a square following an opening shape of an opened heater by using an opened heater having an opening shape of a square.

Further, the present invention provides a continuous production apparatus for crystalline silicon, characterized by including at least: a crucible capable of retaining melted silicon; a heating means capable of maintaining a temperature inside the crucible to a melting point of silicon or higher and capable of forming a negative temperature gradient upward from the crucible; a pulling means capable of holding and pulling solidified crystalline silicon at a predetermined rate; and an opened heater provided above the melted silicon, having an opening of a predetermined shape, and capable of maintaining a temperature at a melting point of silicon or higher.

### BRIEF DESCRIPTION OF THE DRAWINGS

FIG. 1 is a diagram showing a structure of a continuous production apparatus for polycrystalline silicon suitable for carrying out the present invention;

FIG. 2 is a partial diagram of FIG. 1 illustrating a function of an opened heater;

FIG. 3 is a diagram showing a structure of a batch-type production apparatus for polycrystalline silicon employing a conventional unidirectional solidification method; and

FIG. 4 is a diagram showing a structure of a solar cell employing a polycrystalline silicon substrate obtained in Example 2.

### DESCRIPTION OF THE PREFERRED EMBODIMENTS

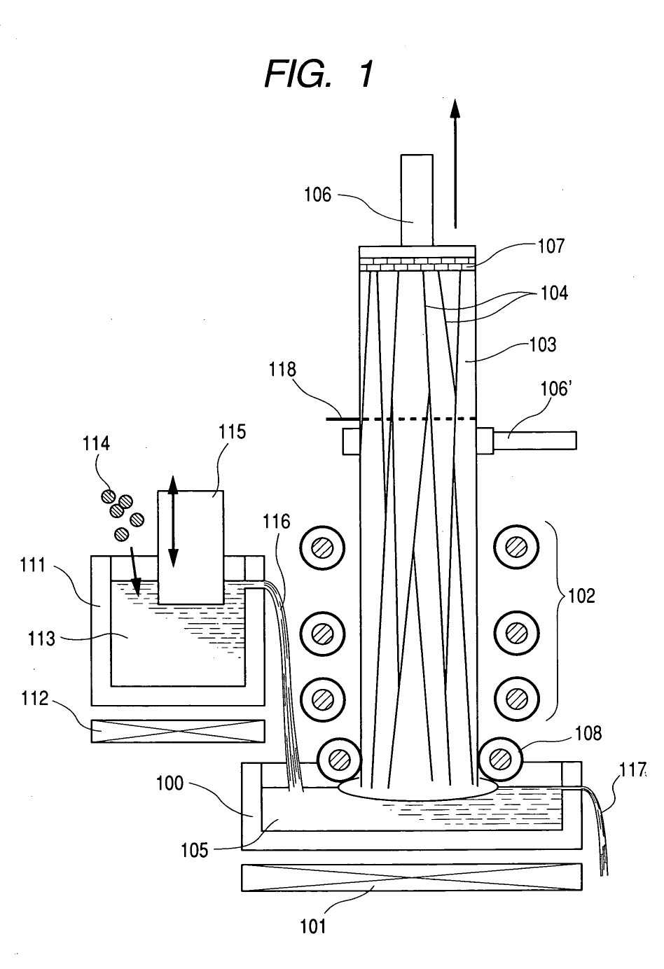

FIG. 1 is an example of a production apparatus for crystalline silicon suitable for carrying out the present invention, and a gist of the method of the present invention will be described with reference to FIG. 1. Hereinafter, a production apparatus for polycrystalline silicon and a production method for polycrystalline silicon will be specifically described in the present specification. The following embodiment and examples may be obviously applied to a production apparatus for single crystal silicon and a production method for the same by providing changes within a range of general operation by a person skilled in the art. A main crucible 100 is heated from a base by a main heater 101, and melted raw material silicon 105 is retained inside the main crucible 100. Polycrystalline silicon 103 held by a pulling means 106 is continuously pulled from a liquid surface of the melted silicon 105. Auxiliary heaters 102 are provided on an outer periphery of the pulled polycrystalline silicon. Thus, a negative temperature gradient is provided upward from the main crucible 100, the polycrystalline silicon 103 pulled through the negative temperature gradient is gradually cooled. Reference numeral 104 denotes a grain boundary.

The above mechanism is similar to a mechanism of Czochralski method (see, above-mentioned “Semiconductor Silicon Crystal Technology”, p. 46) employed in growth of single crystal silicon. However, in the present invention, it is characterized in that the polycrystalline silicon 103 is pulled while a sectional shape is formed by passing through an opening portion of an opened heater 108. The opened heater 108 has an opening of a predetermined shape, is provided in a portion slightly above the liquid surface of the melted silicon 105, and is maintained at a temperature slightly higher than the melting point of silicon.

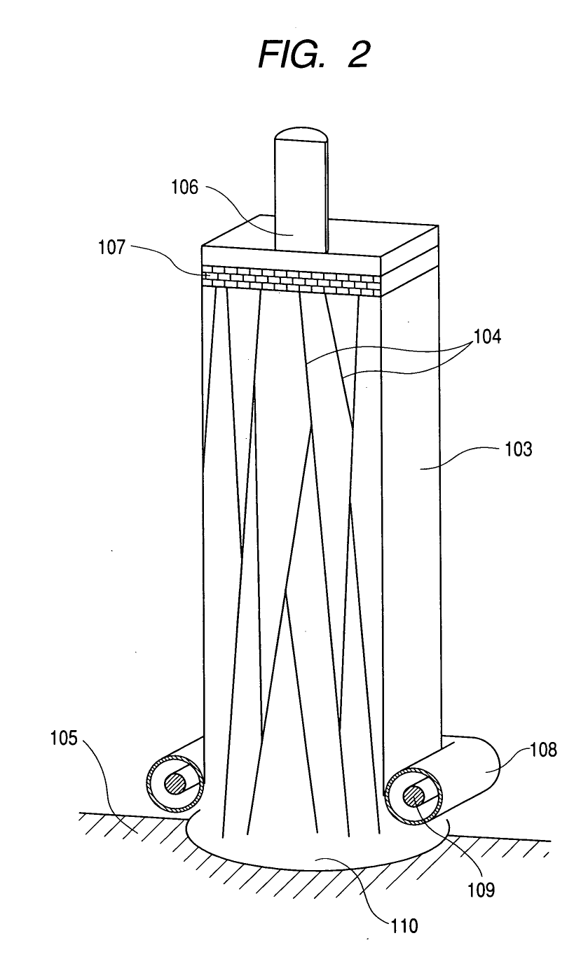

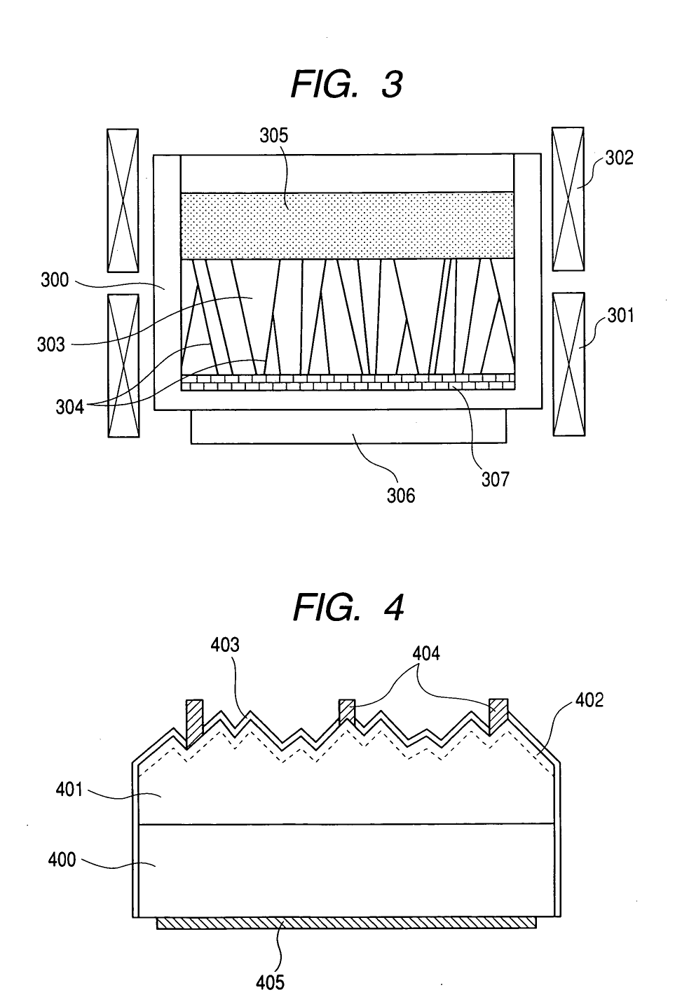

FIG. 2 shows a portion of the production method for polycrystalline silicon in detail for describing a mechanism of the opened heater 108. The opened heater 108 is provided with a sheathed heater 109 inside a pipe of a highly heat resistant material such as quartz glass and has a structure for maintaining a surface of the pipe at a predetermined temperature. An opening shape of the opened heater is preferably a square allowing tight arrangement of many substrates without dead spaces in formation of a module for production of solar cell substrates, for example. Recently, a square having a side of 100 mm, 125 mm, or 150 mm has particularly become a substantial industrial standard.

Pulling of the polycrystalline silicon first involves bringing in contact with the surface of the melted silicon 105, a seed crystal plate 107 of a polycrystalline silicon plate fixed at a tip of the polycrystalline silicon pulling means 106 and maintained at a temperature slightly lower than the melting point of silicon. In contrast to pulling of single crystal silicon, the seed crystal plate 107 need not be crystal silicon and may be a plate of metals, ceramics, or the like as long as the seed crystal plate 107 is formed of a material which is compatible with the polycrystalline silicon 103 across an entire surface and capable of tightly holding the polycrystalline silicon 103. However, use of polycrystalline silicon having well-grown crystal grains as the seed crystal plate 107 is recommended because crystal grains grow easily from initial growth, and the polycrystalline silicon 103 can be held tightly. In FIG. 2, the seed crystal plate 107 is depicted to have an almost the same size and shape with those of the opening of the opened heater 108. In actuality, the seed crystal plate 107 may be smaller than the opening or may have an arbitrary shape such as a disc. Polycrystalline silicon begins to grow on a liquid surface where the seed crystal plate 107 is brought in contact with the surface of the melted silicon 105. Reference numeral 110 denotes a boundary between the melted silicon 105 and the solidified silicon 103. The polycrystalline silicon 103 is then pulled at a predetermined rate by a pulling mechanism. In the present invention, the polycrystalline silicon can be pulled at a larger rate than a standard rate (1 mm/min to 2 mm/min) for pulling the single crystal silicon through the Czochralski method. A cross section of the polycrystalline silicon 103 generally turns into an indefinite shape with pulling and gradually expands. However, when the polycrystalline silicon 103 passes through an opening portion of the opened heater 108, portions of the polycrystalline silicon 103 protruding from the opening is remelted by being in contact with a surface of the opened heater 108 maintained at a temperature higher than the melting point of silicon. Thus, an ingot is shaped into a predetermined sectional shape such as a square following an opening shape of the heater. The polycrystalline silicon 103 need not be rotated or the pulling rate need not be controlled particularly precisely. Thus, the present invention allows pulling of the polycrystalline silicon at a larger rate than the pulling rate of the single crystal silicon through the Czochralski method.

Hereinafter, the present invention will be described with reference to FIG. 1 again. A liquid level of the melted silicon 105 gradually lowers with pulling. In the present invention, raw material silicon is preferably supplied into the main crucible 100 simultaneously with the pulling. The raw material silicon 114 may be directly charged into the main crucible 100. However, supply of silicon 113 melted in advance in an auxiliary crucible 111 heated by an auxiliary heater 112 facilitates control of the temperature or liquid level of the melted silicon 105. Further, control of a position of a float 115 in the melted silicon 113 allows precise control of an amount of supplied silicon 116 introduced into the main crucible 100.

Growth of raw material silicon having a high concentration of metal impurities such as metallurgical grade silicon for a long period of time initially provides polycrystalline silicon 103 containing substantially no metal impurities due to a segregation function as mentioned above. However, remaining impurities gradually accumulate and concentrate in the melted silicon 105. Thus, a concentration of impurities in the grown polycrystalline silicon 103 gradually increases with time. Supply of new raw material silicon into the main crucible 100 in predetermined portions as represented by reference number 116 allows stable growth by maintaining the liquid level of the melted silicon 105. Further, addition of raw material silicon having a relatively low impurity concentration than that of the melted silicon 105 prevents extreme increase of an impurity concentration in the melted silicon. Further, discharge of the melted silicon having been increased impurity concentration in predetermined portions from a place far from a supply port of the raw material silicon 114, as shown by reference numeral 117, allows more efficient decrease of an impurity concentration in the melted silicon 105. Control of the impurity concentration in the melted silicon 105 through a balance between supplied silicon 116 and discharged silicon 117 of silicon allows an impurity concentration in the polycrystalline silicon 103 to be maintained at a specified value or smaller over a long period of time.

The above mechanism allows continuous growth of polycrystalline silicon 103 having constant impurity concentration or crystallinity. Unlimitedly continuous growth of polycrystalline silicon can be carried out by: providing another pulling mechanism 106′ for holding the polycrystalline silicon at an appropriate position; and providing a mechanism for cutting the polycrystalline silicon at a predetermined position with a band saw 118, when the polycrystalline silicon 103 exceeds a predetermined length.

### EXAMPLE 1

Example 1 describes production of a polycrystalline substrate for solar cell silicon substrate using silicon powder obtained from slice scrap formed by a wire-saw. In production of a single crystal silicon substrate or polycrystalline silicon substrate, an ingot is sliced to a thickness of about 200 μm to 800 μm according to size or purpose of the substrate using a wire-saw. The wire used for slicing usually has a diameter of about 200 μm, and thus a high purity silicon scrap having a thickness of 200 μm is produced as a mixture with abrasive grains or a consumed wire. A large amount of the slice scrap contains miscellaneous impurities, and was not readily used. However, the slice scrap usually contains only a small amount of boron or phosphorus, which is hardly removed through the method of the present invention, and thus can be suitably used as a raw material for the method of the present invention.

A slice scrap generated in a production line of a polycrystalline substrate for solar cell silicon substrate was washed with hydrochloric acid, rinsed with ion-exchanged water, and dried, to thereby obtain silicon powder. A polycrystalline substrate for solar cell silicon substrate was produced using the silicon powder and an apparatus shown in FIG. 1. An auxiliary crucible 111 (only one of two is shown) was filled with the silicon powder and heated while vacuum-evacuating, to thereby remove water or gas such as oxygen adsorbed on the powder and to melt the silicon powder. At the same time, heating of a main crucible 100 was initiated. The auxiliary crucible 111 was maintained airtight at this time, and thus the main crucible 100 needed not be vacuum-evacuated. At the time when the silicon powder was melted, a float 115 was pushed into the melted silicon powder, and melted silicon 113 was supplied to the main crucible 100. The melted silicon was supplied up to a predetermined level in the main crucible, and excess silicon was observed to overflow from the main crucible. Thereafter, a pulling mechanism 106 having a seed crystal plate 107 of polycrystalline silicon of 100 mm×100 mm fixed at a tip was lowered, to gradually bring the seed crystal plate in contact with a surface of melted silicon 105. The contact was confirmed by buoyancy on the seed crystal plate 107 due to the melted silicon detected by a load cell (not shown) incorporated in the pulling mechanism 106.

The pulling mechanism 106 was then pulled at a rate of 5 mm/min. An opened heater 108 having an opening of 125 mm×125 mm (inner size) was maintained at a temperature slightly higher than the melting point of silicon. The temperature was controlled such that the temperature was increased when an increase rate of a load detected by the load cell of the pulling mechanism exceeded a predetermined value, and the temperature was decreased when the rate was smaller than a predetermined value. Auxiliary heaters 102 were controlled separately to provide a temperature gradient of an average of −0.7° C./mm upward. The melted silicon 113 was continuously supplied from one auxiliary crucible 111 by controlling a vertical position of the float 115 to prevent a liquid level of the polycrystalline silicon 103 from lowering with pulling. At this time, new raw material silicon was charged into the other auxiliary crucible for melting silicon while vacuum-evacuating the crucible. Thereafter, melting of the raw material silicon and supplying of the raw material silicon to the main crucible 100 were alternatively carried out using the two auxiliary crucibles, to allow continuous supply. On the other hand, an overflow, i.e., discharged silicon 117 of the melted silicon from the main crucible 100 was measured, to control movement of the float 115 for a predetermined overflow amount.

At the time when the height of the thus-grown polycrystalline silicon 103 reached 3 m from the liquid surface, the silicon was held by another pulling means 106′ at a position little over 1 m from the seed crystal plate 107. The polycrystalline silicon was cut with a band saw 118 just above the position held by the pulling means 106′, and pulling of the polycrystalline silicon 103 was continued by the pulling means 106′. At the time when the height of the cut polycrystalline silicon 103 reached 3 m from the liquid surface again and the silicon was held by yet another pulling means 106′ (not shown), to cut 1 m of the polycrystalline silicon again. Thereafter, the two pulling means 106′ were used alternatively, to repeat pulling and cutting.

The growth of the polycrystalline silicon was continued for about 34 hours, and the supply of the melted silicon was stopped. A last portion of the ingot gradually became thin and separated from the liquid surface but was continuously pulled. After a series of operations, 10 polycrystalline silicon ingots each having a length of 1 m were obtained. The ingots each had the same square sectional shape of 125 mm×125 mm as the opening shape of the opened heater 108 and had smooth sides, requiring no additional processing such as cutting or polishing, except for the front portion of the first ingot and the terminal portion of the tenth ingot. Each of the ingots was sliced with a wire-saw, to produce a substrate having a thickness of 300 μm. A surface of the thus-obtained substrate was slightly subjected to etching with fluoro nitric acid, and was measured for specific resistivity. The substrates prepared by slicing any ingot were p-type and each had a specific resistivity in a range of about 1.2 Ωcm to 1.6 Ωcm with slight fluctuation. No trend was observed with a production order of the ingots from which the substrates were sliced, and no change in size or shape of the crystal grains was observed. Thus, the result confirmed that substrates having uniform characteristics can be obtained.

Example 1 employed scrap generated through slicing of a polycrystalline substrate for solar cell silicon substrate as a raw material, and an original substrate for solar cell had a specific resistivity of about 1.0 Ωcm to 1.4 Ωcm. A difference in specific resistivity between the two substrates is small and the substrate of the present invention with the above specific resistivity can be sufficiently used. A specific resistivity can be adjusted to the same value as that of the original polycrystalline substrate for solar cell silicon substrate by adding a predetermined amount of boron to the supplied silicon raw material 114 if required.

Next, solar cells were produced using the polycrystalline silicon substrate formed through the method of the present invention and the original polycrystalline silicon substrate for comparison. First, a phosphorus diffusing agent was applied to a surface of a silicon substrate and was diffused at 850° C. for 30 minutes, to thereby form an n+ layer. A silicon nitride film having a thickness of about 800 Å was deposited through a plasma CVD process as an antireflective film. Further, a pattern of a grid electrode with a silver paste and a pattern of an Al electrode were screen printed on a front side and a back side of the substrate, respectively. The whole was calcined at 850° C. for about 2 minutes and a periphery surface of the substrate was subjected to etching to prevent shunt, to thereby produce a solar cell. Conversion efficiencies of the produced solar cells were measured with a solar simulator having a spectrum of AM1.5. A conversion efficiency of the solar cell for comparison was 14%. A conversion efficiency of the solar cell employing the substrate of the present invention was 13% to 14% with slight fluctuation. However, no trend was observed with a production order of the ingots from which the substrates were sliced. Thus, the result confirmed that solar cell substrates having uniform characteristics can also be obtained.

### EXAMPLE 2

Example 2 employed metallurgical grade silicon prepared by directly reducing silica stone as the most inexpensive and readily available silicon raw material. Metallurgical grade silicon is not produced in Japan and is imported from Norway, Brazil, China, and the like. The metallurgical grade silicon generally has a nominal purity of 98% to 99.5%, and type and concentration of impurities actually contained differ by the silica stone raw material. Table 1 shows a typical example.

TABLE 1

| Impurity | Concentration |
|---|---|
| Fe | 2 × 10¹⁹ cm⁻³ |
| Cr | 1 × 10¹⁹ cm⁻³ |
| Cu | 2 × 10¹⁸ cm⁻³ |
| B | 4 × 10¹⁸ cm⁻³ |
| P | 1 × 10¹⁸ cm⁻³ |

Main impurities include heavy metals such as Fe, Cr, and Cu. Those impurities form a deep level in silicon to serve as a recombination center. Thus, a substrate for solar cell employing such silicon containing heavy metals has significantly deteriorated characteristics. In addition, the heavy metals easily diffuse and contamination thereof spreads extensively in a semiconductor device or solar cell production process. Thus, the heavy metals are particularly unfavorable impurities. However, the method of the present invention confirms that the impurities can be removed to an impurity concentration to 0.1 ppm or less.

Further, metallurgical grade silicon contains impurities serving as dopants such as boron or phosphorus. Polycrystals of silicon containing a relatively high concentration of boron as in Table 1 are generally p-type but may be n-type depending on the raw material used, and a specific resistivity is also inconsistent. Thus, metallurgical grade silicon generally cannot be used as it is for solar cell production even through the method of the present invention. However, a substrate produced through the method of the present invention which can be suitably used as a polycrystalline substrate for solar cell substrate includes: a base formed by adding a large amount of boron to raw material silicon, to produce polycrystalline silicon having low resistivity; and a polycrystalline silicon layer having high purity and predetermined specific resistivity, grown on a surface of the base. A required thickness of the polycrystalline silicon layer only needs to be about ⅕ to 1/10 times the thickness of a general polycrystalline silicon substrate, resulting in resource saving of high purity silicon and in reduction of substrate production cost.

In Example 2, a production method for a substrate and a production process for a solar cell employing the substrate will be described with reference to FIG. 4. A polycrystalline ingot was prepared using the same apparatus as in Example 1, through basically the same steps as in Example 1, and using a square opened heater 108 having an opening shape of 125 mm×125 mm except that metallurgical grade silicon nugget from Brazil was used and 200 ppm by weight of metal boron was added with respect to the silicon nugget. An amount of the overflow, i.e., discharged silicon 117 of the melted silicon from the main crucible 100 was controlled to 3 times that in Example 1. Further, supply of raw material silicon (supplied silicon 116) was determined so that-a liquid level of the melted silicon 105 was maintained under the same conditions. An amount of the overflow of the melted silicon was increased to more rapidly discharge impurities retained in the melted silicon because the raw material silicon contains impurities at a concentration higher than that in Example 1. The obtained polycrystalline silicon ingot was sliced into a thickness of 300 μm only, to provide a base 400 of 125 mm×125 mm×300 μm. The base had a conductivity type of a p-type and a specific resistivity of 0.02 Ωcm.

A polycrystalline silicon layer 401 was grown on a surface of the base 400 through liquid phase growth. Metal indium was charged into a crucible and was melted by heating at 950° C. A p-type solar cell-grade polycrystalline silicon substrate was set and was immersed in melted indium to melt silicon into indium to saturation. The polycrystalline silicon substrate was the pulled from the melt. An atmosphere surrounding the crucible was replaced by hydrogen, and the melt was cooled at a rate of 1° C./min. At a melt temperature of 945° C., the base was immersed in the melt for an hour for continued growth and pulled from the melt. Indium adhesion was not observed on the base or jigs holding the base. Indium was removed just in case by immersing the base in hydrochloric acid, rinsed with ion-exchanged water, and dried. The polycrystalline silicon layer 401 having a thickness of about 30 μm was grown on the base 400. The polycrystalline silicon layer 401 had crystal grains having the same size and pattern as those of the base 400, confirming that the layer had taken over satisfactory crystallinity of the base. Thus, a polycrystalline substrate for solar cell silicon substrate was formed. Fine irregularities of a pitch of 5 μm to 10 μm were observed by a metallurgical microscope on a surface of the substrate. The observation by a metallurgical microscope of a further cutout cross section indicated that the irregularities consist of a terrace in one direction by crystal grains and provides a facet surface formed with crystal growth. The base 400 serves as a seed crystal for growth of the polycrystalline silicon layer 401, is p-type, and has a resistivity lower than that of the polycrystalline silicon layer 401. Thus, the base 400 exhibits a back surface field effect on the polycrystalline silicon layer 401, to enhance solar cell efficiency.

Next, a solar cell was prototyped using the thus-obtained polycrystalline silicon substrates. An application liquid containing phosphorus was applied on each of the substrates with a spinner for forming an emitter layer 402. The application liquid was dried, and the substrates were charged and arranged into a horizontal heat treat furnace with two back surfaces facing each other. Phosphorus was thermally diffused in a nitrogen atmosphere at 900° C., and remaining application liquid was removed through etching. Then, the substrates were charged into a plasma CVD apparatus for each forming a nitride silicon film 403 as an antireflective film. The nitride silicon film 403 having a predetermined thickness was deposited at a substrate temperature of 300° C. by: passing a mixture of a silane gas, an ammonium gas, and a nitrogen gas; applying an RF voltage to a cathode facing the substrate; and continuing discharge for 5 minutes. The deposited nitride silicon film 403 was deposited to cover end faces. Next with a screen printer, a pattern was printed with an alumina paste and dried as a back surface electrode 405, and a pattern was printed on a front surface with a silver paste and dried as a grid electrode 404. The whole was charged into an infrared belt firing furnace. A 450° C. zone and an 800° C. zone were provided in the firing furnace, and the substrates were arranged on the belt. The substrates were passed through each of the zones in a stream of a large volume of air, to thereby calcine the pastes. Silver particles penetrated the antireflective film 403 to reach the emitter layer 402, providing satisfactory electrical contact with the emitter layer 402. On the other hand, the alumina paste formed satisfactory contact with the back surface of the base 400 through melting of aluminum, providing the back surface electrode 405.

A conversion efficiency of the solar cell produced through the above process was measured with a solar simulator having an irradiation spectrum of AM1.5. A conversion efficiency of the solar cell fell within a range of 13% to 13.5%, confirming that a satisfactory solar cell can be obtained using polycrystalline silicon produced through the method of the present invention.

In Example 2, a high purity silicon layer having a thickness of 30 μm provided a conversion efficiency very close to that of conventionally used polycrystalline silicon substrate having a thickness of about 300 μm (consuming a thickness of 500 μm including slicing area). The result confirmed that the present invention allows effective utilization of silicon resource and contribution to additional cost reduction of the solar cell.

### EXAMPLE 3

Example 3 describes a production example of a polycrystalline silicon target for a large-scale sputtering. Large liquid crystal displays have spread recently, and polycrystalline silicon films used in pixel driving TFT correspondingly must be deposited uniformly on large substrates. Highly uniform deposition on a large substrate can be carried out using a relatively small deposition apparatus by depositing on a front surface of a strip target having a length equal to or larger than the width of the substrate while the substrate is moved vertically with respect to a longitudinal direction of the target. Thus, efficient production of a target material having a large aspect ratio is demanded. For application of a target material to TFT in particular, the target material must have a precisely uniform specific resistivity for enhancing uniformity in Vth characteristics of TFT. Further, the size of crystal grains affects a sputtering yield and may cause ununiform local thickness. Thus, obtaining crystal grains having a predetermined uniform size are also demanded.

Example 3 employed as crystalline silicon, silicon remaining in a crucible after pulling of a single crystal silicon ingot (that is, silicon remaining in crucible). A specific resistivity thereof initially measured was 0.4 Ωcm. A target specific resistivity of the ingot is 0.2 Ωcm. Silicon block remaining in crucible was crushed into a size of about 1 cm, washed with hydrochloric acid, rinsed with ion-exchanged water, and dried. The thus-obtained raw material was used for production of polycrystalline silicon using an apparatus having basically the same structure as that used in Example 1. The apparatus includes an opened heater 108 having a rectangle opening shape of 350 mm×100 mm and has other portions designed to a large scale as the opened heater. A production process was basically the same as in Example 1 expect that: silicon was sampled from overflowing melted silicon 117 and was solidified as droplets to measure a specific resistivity; and an amount of metal boron added to the raw material silicon 105 was adjusted to provide the precise target specific resistivity. Thus, 5 ingots were grown.

The grown ingots were sliced into a thickness of 6 mm, to thereby obtain target materials of 350 mm×100 mm×6 mm each. A specific resistivity of the sliced target materials from each of the ingots fell within a range of 0.2 Ωcm to 0.25 Ωcm with slight fluctuation, and crystal grains were large and uniform.

As described above, polycrystalline silicon having uniform specific resistivity and crystal grain size at predetermined values with a small amount of harmful impurities such as heavy metals can be continuously produced even when low quality raw material silicon such as metallurgical grade silicon is used according to preferable examples of the present invention. Further, a single crystal silicon ingot or a polycrystalline silicon ingot each having a desired sectional shape can be obtained. Thus, shaping an ingot into a final product is easy with small waste of the raw material, which is particularly effective for production of polycrystalline substrate for solar cell silicon substrates.

This application claims priority from Japanese Patent Application No. 2003-333091 filed on Sep. 25, 2003, which is hereby incorporated by reference herein.

1. A continuous production method of crystalline silicon, comprising the steps of:
retaining melted silicon in a crucible;
solidifying a portion close to a surface of raw material silicon by providing a negative temperature gradient upward from the crucible;
holding the solidified crystalline silicon by a pulling means; and
pulling the solidified crystalline silicon at a predetermined rate, while shaping a sectional shape of the solidified crystalline silicon by bringing the solidified crystalline silicon in contact with an opened heater when the solidified crystalline silicon passes through an opening portion of the opened heater having an opening of a predetermined shape and maintained at a temperature higher than a melting point of the raw material silicon.

2. The continuous production method for crystalline silicon according to claim 1, wherein the crystalline silicon pulling means has a seed crystal plate of crystalline silicon fixed at a tip; and the seed crystal plate is brought in contact with a surface of the melted silicon to begin solidification of silicon.

3. The continuous production method for crystalline silicon according to claim i, wherein the melted silicon is maintained at a predetermined liquid level by supplying the raw material silicon into the crucible during pulling of the crystalline silicon.

4. The continuous production method for crystalline silicon according to claim 3, wherein the raw material silicon supplied is prepared by melting in another crucible in advance.

5. The continuous production method for crystalline silicon according to claim 1, wherein the melted silicon is maintained at a predetermined liquid level by discharging the melted silicon retained in the crucible to outside of the crucible at a predetermined ratio and supplying the raw material silicon into the crucible during pulling of the crystalline silicon.

6. The continuous production method for crystalline silicon according to claim 5, wherein the raw material silicon supplied is prepared by melting in another crucible in advance.

7. The continuous production method for crystalline silicon according to claim 1, wherein the raw material silicon used comprises metallurgical grade silicon.

8. The continuous production method for crystalline silicon according to claim 1, wherein a predetermined portion in an upper portion of the crystalline silicon is cut off every time the pulled crystalline silicon reaches a predetermined length; and the remaining crystalline silicon is continuously pulled by the pulling means.

9. The continuous production method for crystalline silicon according to claim 1, wherein the crystalline silicon has a sectional shape of a square following an opening shape of an opened heater by using an opened heater having an opening shape of a square.

10. A continuous production apparatus for crystalline silicon, comprising:
a crucible capable of retaining melted silicon;
a heating means capable of maintaining a temperature inside the crucible to a melting point of silicon or higher and capable of forming a negative temperature gradient upward from the crucible;
a pulling means capable of holding and pulling solidified crystalline silicon at a predetermined rate; and
an opened heater provided above the melted silicon, having an opening of a predetermined shape, and capable of maintaining a temperature at a melting point of silicon or higher.
